(19) United States
(12) Patent Application Publication
(10) Pub. No.: US 2013/0220414 A1
(43) Pub. Date: Aug. 29, 2013

(54) BACK ELECTRODE TYPE SOLAR CELL

(71) Applicant: Masatsugu Kohira, Osaka-shi (JP)

(72) Inventor: Masatsugu Kohira, Osaka-shi (JP)

(73) Assignee: Sharp Kabushiki Kaisha, Osaka-shi, Osaka (JP)

(21) Appl. No.: 13/884,162

(22) PCT Filed: Oct. 27, 2011
(86) PCT No.: PCT/JP2011/074773

§ 371 Date: May 8, 2013

(30) Foreign Application Priority Data
Nov. 17, 2010 (JP) 2010-256580

(51) Int. Cl. H01L 31/0224

(52) U.S. Cl. CPC H01L 31/022441
USPC 136/256

(57) ABSTRACT

There is provided a back electrode type solar cell (1, 51) including: a silicon substrate (4) of a first conductivity type or a second conductivity type; first and second conductivity type semiconductor regions (9, 10) provided at a back surface of the silicon substrate (4) opposite to a light-receiving surface of the silicon substrate (4); an electrode (2, 3) for the first conductivity type provided in the first conductivity type semiconductor region (9, 10); an electrode (2, 3) for the second conductivity type provided in the second conductivity type semiconductor region (9, 10); and a peripheral edge semiconductor region (71, 72) provided at a surrounding of a forming region of the first conductivity type semiconductor region (9, 10) and the second conductivity type semiconductor region (9, 10), the peripheral edge semiconductor region (71, 72) being out of contact with the electrode (2, 3) for the first conductivity type and the electrode (2, 3) for the second conductivity type.

### TECHNICAL FIELD

The present invention relates to a back electrode type solar cell having a light-receiving surface and an opposite surface provided with electrodes, and more specifically to a structure at a back surface of the back electrode type solar cell.

### BACKGROUND ART

In recent years, the solar cells that convert solar energy directly into electrical energy are increasingly, rapidly expected as an energy source for the next generation in view of global environmental issues in particular. While there are a variety of solar cells such as those using compound semiconductor or organic material, those using silicon crystal are currently mainstream.

A type of solar cell currently most produced and sold has a structure in which a light receiving surface as a surface on which solar light is incident and a back surface opposite to the light-receiving surface are provided with electrodes, respectively.

However, if the light-receiving surface is provided with an electrode, the electrode reflects and absorbs light and the solar light that is incident is reduced by the area of the electrode, and accordingly, a back electrode type solar cell having electrodes only at the back surface is developed.

FIG. 8 is a schematic cross sectional view of a conventional back electrode type solar cell disclosed in Patent Document 1. Hereinafter, a conventional back electrode type solar cell 101 will be described.

An n type silicon wafer 104 has a concave-convex structure 105, and an n type front surface side diffusion region 106 that is a front surface field (FSF) layer on a light-receiving surface side. Then, on concave-convex structure 105, from a side of n type silicon wafer 104, a dielectric passivation layer 108 that contains silicon dioxide and an antireflection coating 107 that contains silicon nitride are provided in this order.

Furthermore, n type silicon wafer 104 has a back surface provided with an oxide layer 109. Furthermore, on a back surface side of n type silicon wafer 104 an n+ region 110 in which an n type impurity is doped and a p+ region 111 in which a p type impurity is doped alternately, are provided A metal contact for n type 102 is provided on n+ region 110, and a metal contact for p type 103 is provided on p+ region 111.

### CITATION LIST

### Patent Document

PTD 1: Japanese National Patent Publication No. 2008-532311

### SUMMARY OF INVENTION

### Technical Problem

In a back electrode type solar cell module having a plurality of back electrode type solar cells connected in series or parallel, when a portion of the back electrode type solar cell module is unexposed to light and thus shaded in operation, reverse bias voltage is applied to a shaded back electrode type solar cell in a relationship with the other back electrode type solar cells.

If the back electrode type solar cell has a p+ region which has a conductivity type different from that of the n type silicon wafer, and a metal contact for the p type is connected to that region, as in the back electrode type solar cell of PTD 1, the reverse bias voltage applied to the back electrode type solar cell facilitate causing a leakage current passing through the peripheral edge into the metal contact for the p type.

The present invention has been made in view of the above issue and an object of the present invention is to achieve a back electrode type solar cell that can reduce an occurrence of a leakage current passing through a peripheral edge of a back surface of the back electrode type solar cell into an electrode when reverse bias voltage is applied to the back electrode type solar cell.

### Solution to Problem

The present invention provides a back electrode type solar cell including: a silicon substrate of a first conductivity type or a second conductivity type; a first conductivity type semiconductor region and a second conductivity type semiconductor region provided at a back surface of the silicon substrate opposite to a light-receiving surface of the silicon substrate; an electrode for the first conductivity type provided in the first conductivity type semiconductor region; an electrode for the second conductivity type provided in the second conductivity type semiconductor region; and a peripheral edge semiconductor region provided at the back surface of the silicon substrate and surrounding a region provided with the first conductivity type semiconductor region and the second conductivity type semiconductor region, the peripheral edge semiconductor region being out of contact with the electrode for the first conductivity type and the electrode for the second conductivity type.

Herein, in the present back electrode type solar cell, preferably, the second conductivity type semiconductor region is provided at a surrounding of the first conductivity type semiconductor region and the peripheral edge semiconductor region has a conductivity type identical to that of the first conductivity type semiconductor region.

Furthermore, in the present back electrode type solar cell, preferably, of the first conductivity type semiconductor region and the second conductivity type semiconductor region, a semiconductor region of a conductivity type different from that of the silicon substrate has a larger total area.

Furthermore, in the present back electrode type solar cell, preferably, of the electrode for the first conductivity type and the electrode for the second conductivity type, outermost electrodes disposed on the back surface of the silicon substrate are electrodes for a single conductivity type.

Furthermore, in the present back electrode type solar cell, preferably, of the electrode for the first conductivity type and the electrode for the second conductivity type, outermost electrodes disposed on the back surface of the silicon substrate are electrodes for a conductivity type different from that of the peripheral edge semiconductor region.

Furthermore, in the present back electrode type solar cell, preferably, a light-receiving surface diffusion layer of a conductivity type identical to that of the silicon substrate is provided on a light-receiving surface side of the silicon substrate.

Furthermore, preferably, the present back electrode type solar cell further includes: a light-receiving surface passivation film provided on the light-receiving surface diffusion layer; and an anti-reflection film provided on the light-receiving surface passivation film, and the anti-reflection film is titanium oxide film containing an impurity of a conductivity type identical to that of the silicon substrate.

### Advantageous Effects of Invention

The present back electrode type solar cell having a back surface with a peripheral edge having a peripheral edge semiconductor region that is not connected to an electrode can reduce an occurrence of a leakage current otherwise passing through the peripheral edge of the back surface of the back electrode type solar cell into the electrode when reverse bias voltage is applied to the back electrode type solar cell.

### BRIEF DESCRIPTION OF DRAWINGS

FIG. 1 is a schematic plan view of a back surface of a back electrode type solar cell of a first embodiment.

FIG. 2(a) is a schematic cross sectional view along a line II-II of FIG. 1, FIG. 2(b) is a schematic enlarged cross sectional view of a portion of a light-receiving surface of an n type silicon substrate shown in FIG. 2(a), and FIG. 2(c) is a schematic enlarged cross sectional view for illustrating a difference in thickness between an n++ region and a p+ region shown in FIG. 2(a).

FIG. 3 is a schematic plan view of a back surface of an n type silicon substrate when an electrode for n type, an electrode for p type, and a back surface passivation film are removed from the back electrode type solar cell of the first embodiment.

FIGS. 4(a) to 4(j) are schematic cross sectional views for illustrating an example of a method for producing the back electrode type solar cell of the first embodiment.

FIG. 5 is a schematic plan view of a back surface of a back electrode type solar cell of a second embodiment.

FIG. 6(a) is a schematic cross sectional view along a line VI-VI of FIG. 5, FIG. 6(b) is a schematic enlarged cross sectional view of a portion of a light-receiving surface of an n type silicon substrate shown in FIG. 6(a), and FIG. 6(c) is a schematic enlarged cross sectional view for illustrating a difference in thickness between an n++ region and a p+ region shown in FIG. 6(a).

FIG. 7 is a schematic plan view of a back surface of an n type silicon substrate when an electrode for n type, an electrode for p type, and a back surface passivation film are removed from the back electrode type solar cell of the second embodiment.

FIG. 8 is a schematic cross sectional view of a conventional back electrode type solar cell.

### DESCRIPTION OF EMBODIMENTS

Hereinafter, the present invention will be described in embodiments. In the figures of the present invention, identical or corresponding components are identically denoted.

### First Embodiment

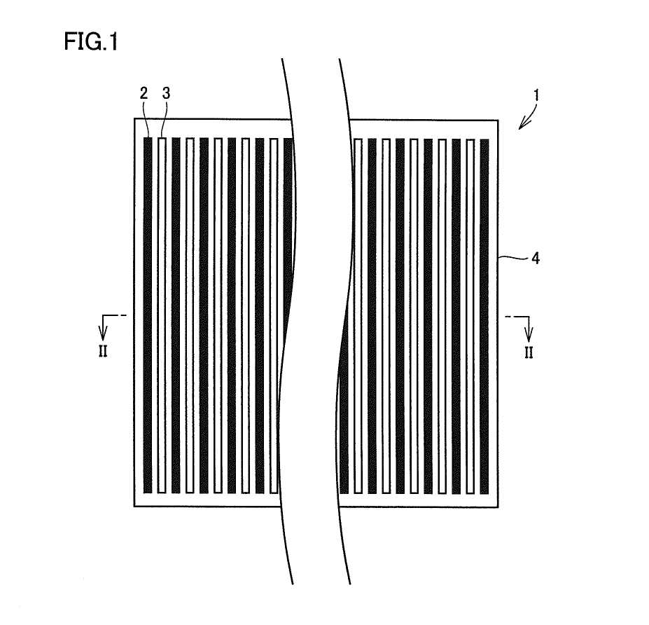

FIG. 1 shows a schematic plan view of a back surface of a back electrode type solar cell of a first embodiment, and, as shown in FIG. 1, a back electrode type solar cell 1 has an n type silicon substrate 4 that is a monocrystalline silicon substrate having a light-receiving surface and an opposite, back surface, and back electrode type solar cell 1 has electrodes only on the back surface that are a strip-shaped electrode for n type 2 and a strip-shaped electrode for p type 3 disposed alternately.

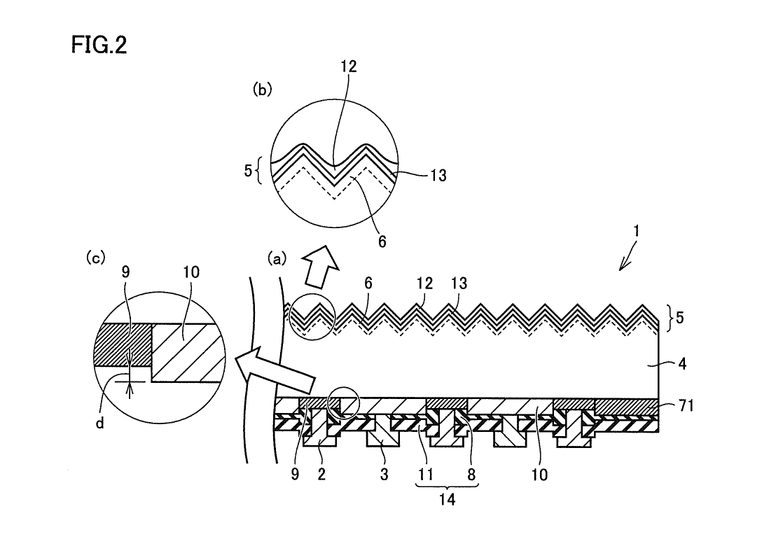

FIG. 2(a) shows a schematic cross sectional view along a line II-II of FIG. 1, and FIG. 2(b) shows a schematic enlarged cross sectional view of a portion of the light-receiving surface of n type silicon substrate 4 shown in FIG. 2(a), and FIG. 2(c) shows a schematic enlarged cross sectional view for illustrating a difference in thickness between an n++ region and a p+ region shown in FIG. 2(a). As shown in FIG. 2(a), n type silicon substrate 4 has a concave-convex structure 5 that is a textured structure on its light-receiving surface side. Concave-convex structure 5 can have concaves and convexes in an order for example of several to several tens micrometers.

Furthermore, as shown in FIG. 2(a) and FIG. 2(b), throughout the light-receiving surface side of n type silicon substrate 4, a light-receiving surface diffusion layer 6 that is an n+ region is provided as a front surface field (FSF) layer, and light-receiving surface diffusion layer 6 has a light-receiving surface passivation film 13 on its light-receiving surface side. Furthermore, an anti-reflection film 12 is provided on light-receiving surface diffusion layer 6. Light-receiving surface diffusion layer 6 has an n type impurity concentration larger than that of n type silicon substrate 4.

Note that light-receiving surface passivation film 13 is formed for example of silicon oxide film and can have a thickness for example of not less than 15 nm and not more than 200 nm, preferably not less than 15 nm and not more than 60 nm.

Furthermore, anti-reflection film 12 is formed for example of titanium oxide film and can have a thickness for example of not less than 10 nm and not more than 400 nm. Furthermore, anti-reflection film 12 may for example contain phosphorus, and in that case, anti-reflection film 12 can have a phosphorus concentration for example of not less than 15% by mass and not more than 35% by mass in the form of phosphorus oxide. Note that being contained in the form of phosphoric oxide in an amount of not less than 15% by mass and not more than 35% by mass of anti-reflection film 12 means that anti-reflection film 12 has a phosphoric oxide content corresponding to 15% by mass to 35% by mass of the entirety of anti-reflection film 12.

Furthermore, as shown in FIG. 2(a), on the back surface of n type silicon substrate 4, from a side of n type silicon substrate 4, a second back surface passivation film 8 and a first back surface passivation film 11 are provided in this order to provide a back surface passivation film 14 structured of two layers.

Furthermore, an n++ region 9 that is an n type semiconductor region and a p+ region 10 that is a p type semiconductor region are provided in the back surface of n type silicon substrate 4 alternately and adjacently. With n++ region 9 and p+ region 10 provided alternately adjacently, such a phenomenon occurs that when back electrode type solar cell 1 is biased in a reverse direction (or reverse bias voltage is applied to back electrode type solar cell 1), substantially no current passes until breakdown voltage is reached, as in a normal diode, and when voltage larger than breakdown voltage is applied, a large current (a breakdown current) passes and no larger voltage is applied to back electrode type solar cell 1. This breakdown current passes in a region in which n++ region 9 and p+ region 10 are immediately adjacent, and back electrode type solar cell 1 can thus avoid partially applied voltage, and hence local current leakage and hence heat otherwise generated thereby.

As shown in FIG. 2(c), n++ region 9 has a surface shallower by a depth B than that of p+ region 10 and n++ region 9 on the back surface of n type silicon substrate 4 has a surface concaved as compared with that of a region on the back surface of n type silicon substrate 4 other than n++ region 9 and n++ region 9 and p+ region 10 are disposed to form a concave. Note that depth d is on an order of several tens nanometers for example. Furthermore, electrode for n type 2 is provided on n++ region 9, and electrode for p type 3 is provided on p+ region 10.

Back surface passivation film 14 on n++ region 9 and back surface passivation film 14 on p+ region 10 have a difference in thickness and back surface passivation film 14 on n++ region 9 is larger in thickness than back surface passivation film 14 on p+ region 10.

Furthermore, a p+ region 71 that is a peripheral edge semiconductor region that has no electrodes and is thus out of contact with any electrodes, is provided at the peripheral edge of the back surface of n type silicon substrate 4.

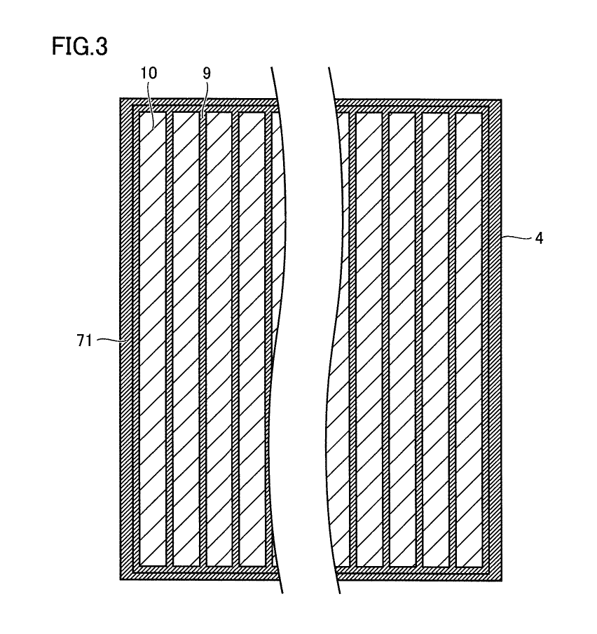

FIG. 3 shows a schematic plan view of the back surface of n type silicon substrate 4 when electrode for n type 2, electrode for p type 3, and back surface passivation film 14 are removed from back electrode type solar cell 1 of the first embodiment. Note that in the present embodiment back electrode type solar cell 1 has p+ region 71 at a surrounding of a forming region of n++ region 9 and p+ region 10 in the back surface of n type silicon substrate 4 as a peripheral edge semiconductor region that is a semiconductor region out of contact with any electrodes. Furthermore, n++ region 9 is provided to surround strip-shaped p+ region 10, and p+ region 10 and p+ region 71 have the same, p type conductivity type.

As shown in FIG. 3, by providing p+ region 71 as a peripheral edge semiconductor region of a conducting type that is different from that of n++ region 9, even if p+ region 71 is provided at the outside of the forming region of n++ region 9 and p+ region 10, n++ region 9 and p+ region 10 can be electrically separated. Even if back electrode type solar cell 1 is biased in a reverse direction (or a reverse bias voltage is applied thereto), it can reduce an occurrence of a leakage current passing through the peripheral edge of back electrode type solar cell 1 into an electrode, since p+ region 71 as a peripheral edge semiconductor region is out of contact with any electrodes.

Furthermore, in the back surface of back electrode type solar cell 1, of n++ region 9 and p+ region 10, p+ region 10 as a semiconductor region of a conductivity type that is different from that of n type silicon substrate 4 preferably has a larger total area. In that case, there is a tendency that back electrode type solar cell 1 provides a short-circuit current in an increased amount. Furthermore, in that case, n++ region 9 may be divided in a direction perpendicular to its lengthwise direction, and p+ region 10 can be provided between the divisions of n++ region 9. Furthermore, in that case, p+ region 10 may be divided in a direction perpendicular to its lengthwise direction, and n++ region 9 can be provided between the divisions of p+ region 10.

Note that while in the example shown in FIG. 3 n++ regions 9 are all connected to form a single semiconductor region, it is not a requirement to connect n++ regions 9 altogether. Furthermore, while in the example shown in FIG. 3 p+ region 10 divided into a plurality thereof, p+ region 10 may have a portion connected to another portion thereof.

Furthermore, in back electrode type solar cell 1 of the first embodiment, outermost, opposite electrodes disposed in the back surface of n type silicon substrate 4, are electrodes for n type 2, respectively, which allows the back surface of back electrode type solar cell 1 to be a rotationally symmetrical structure. Accordingly, when a plurality of back electrode type solar cells 1 are aligned to produce a solar cell module, back electrode type solar cell 1 shown in FIG. 1 may be placed with its back surface upside down.

Furthermore, in back electrode type solar cell 1 of the first embodiment, of electrode for n type 2 and electrode for p type 3, outermost, opposite on electrodes for n type 2 on the back surface of n type silicon substrate 4 are electrodes for a conductivity type that is different from that of p+ region 71 as a peripheral edge semiconductor region.

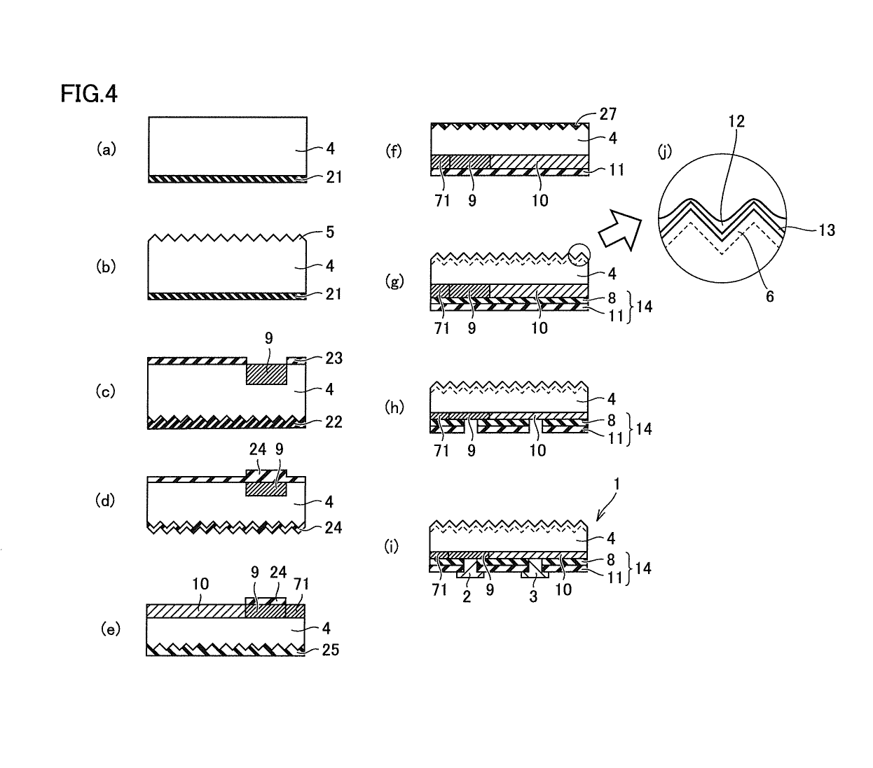

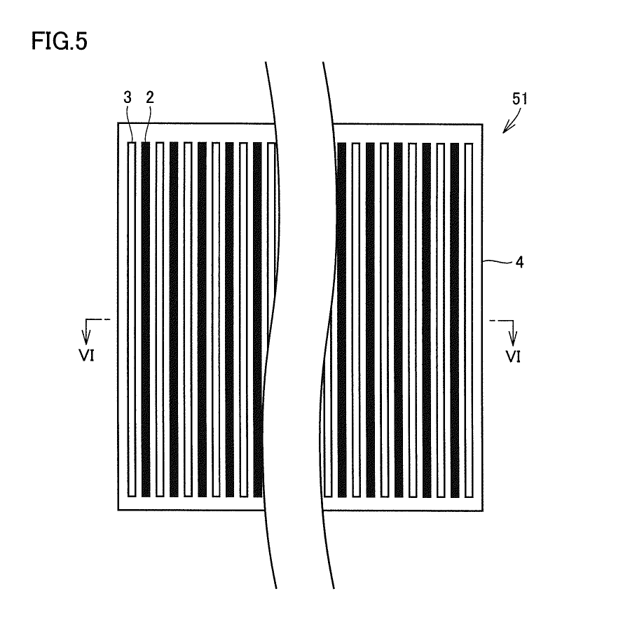

Hereinafter, turning to schematic cross sectional views of FIGS. 4(a) to 4(j), an example of a method for producing the back electrode type solar cell of the first embodiment will be described.

Initially, as shown in FIG. 4(a), a texture mask 21 is provided on a back surface of n type silicon substrate 4 (the back surface of n type silicon substrate 4) opposite to a surface that serves as a light-receiving surface of n type silicon substrate 4 (the light-receiving surface of n type silicon substrate 4). Herein, n type silicon substrate 4 can be a substrate formed for example of a 100-μm-thick n type monocrystalline silicon. Furthermore, texture mask 21 can be silicon nitride film or the like for example. Furthermore, texture mask 21 can be provided for example by a CVD (chemical vapor deposition) method, a sputtering method or the like.

Then, as shown in FIG. 4(b), n type silicon substrate 4 is provided with concave-convex structure 5 at the light-receiving surface. Concave-convex structure 5 can be a textured structure for example. Concave-convex structure 5 can be formed for example by etching the light-receiving surface of n type silicon substrate 4 with an aqueous solution of sodium hydroxide or an aqueous solution of potassium hydroxide or a similar alkaline aqueous solution that has isopropyl alcohol added thereto and is heated to not less than 70° C. and not more than 80° C.

Then, as shown in FIG. 4(c), n++ region 9 is provided in a portion of the back surface of n type silicon substrate 4. Herein, n++ region 9 can be provided for example as follows:

Initially, texture mask 21 on the back surface of n type silicon substrate 4 is removed. Then, a diffusion mask 22, such as silicon oxide film, is provided on the light-receiving surface of n type silicon substrate 4. Then, a masking paste is applied on the back surface of n type silicon substrate 4 at a region other than that to be provided with n++ region 9, and the masking paste then undergoes a heat treatment to provide a diffusion mask 23. Subsequently, vapor-phase diffusion using POCl₃ is employed to diffuse phosphorus to a portion of the back surface of n type silicon substrate 4 that is exposed from diffusion mask 23 to provide n++ region 9.

Note that the masking paste can contain a solvent, a thickener, and a silicon oxide precursor, for example. Furthermore, the masking paste can be applied for example by ink jet printing, screen printing or the like.

Then, as shown in FIG. 4(d), silicon oxide film 24 is provided on the back and light-receiving surfaces of n type silicon substrate 4. Herein, silicon oxide film 24 can be provided for example as follows. Diffusion masks 22 and 23 and a glass layer provided as phosphorus diffuses in diffusion masks 22 and 23 are removed from n type silicon substrate 4 by a hydrofluoric acid treatment and n type silicon substrate 4 is subsequently thermally oxidized with oxygen or water vapor. Note that n type silicon substrate 4 can be thermally oxidized with oxygen or water vapor by undergoing a heat treatment in an atmosphere of oxygen or water vapor.

Herein, as shown in FIG. 4(d), silicon oxide film 24 at region provided with n++ region 9 on the back surface of n type silicon substrate 4 (silicon oxide film 24 on n++ region 9) can be larger in thickness than silicon oxide film 24 at a region other than n++ region 9 on the back surface of n type silicon substrate 4 (silicon oxide film 24 on a region other than n++ region 9). Silicon oxide film 24 thus shaped can be formed for example as follows. If thermal oxidation using water vapor is performed at 900° C. to provide silicon oxide film 24, silicon oxide film 24 can be provided on n++ region 9 to have a thickness of 250 nm to 350 nm and silicon oxide film 24 can be provided on a region other than n++ region 9 to have a thickness of 70 nm to 90 nm. Herein, a phosphorus concentration of the surface of n++ region 9 before the thermal oxidation is not less than 5×10¹⁹ atoms/cm³, and the thermal oxidation using oxygen is performed in a range of 800° C. to 1000° C. whereas the thermal oxidation using water vapor is performed in a range of 800° C. to 950° C.

Note that in providing p+ region 10 through the following process, it is preferable that a diffusion mask of n++ region 9 has a thickness of not less than 60 nm, and accordingly, silicon oxide film 24 on n++ region 9 and silicon oxide film 24 on the region other than n++ region 9 preferably have a difference in thickness of not less than 60 nm.

Furthermore, when silicon oxide film 24 is provided by the thermal oxidation, different types and concentrations of impurity diffused into the back surface of n type silicon substrate 4 allow the thermal oxidation to grow silicon oxide film 24 at different rates, and when n type silicon substrate 4 has a back surface with high n type impurity concentration, in particular, silicon oxide film 24 can be grown fast. Accordingly, silicon oxide film 24 on n++ region 9 having an n type impurity concentration higher than n type silicon substrate 4 can be larger in thickness than silicon oxide film 24 on the region other than n++ region 9 that has an n type impurity concentration lower than n++ region 9.

Note that silicon oxide film 24 is provided by bonding of silicon and oxygen in the thermal oxidation.

Then, as shown in FIG. 4(e), p+ region 10 is provided at a portion of the back surface of n type silicon substrate 4. P+ region 10 can be provided for example as follows.

Initially, silicon oxide film 24 on the light-receiving surface of n type silicon substrate 4 and silicon oxide film 24 on the back surface of n type silicon substrate 4 at the region other than n++ region 9 are etched away. Herein, the thickness of silicon oxide film 24 on n++ region 9 on the back surface of n type silicon substrate 4 is larger than that of silicon oxide film 24 on a region of the back surface of n type silicon substrate 4 other than n++ region 9, and hence silicon oxide film 24 can be left only on n++ region 9 of the back surface of n type silicon substrate 4. Silicon oxide film 24 on n++ region 9 and silicon oxide film 24 on the region other than n++ region 9 are etched at different rates, respectively, and silicon oxide film 24 on n++ region 9 can thus have a thickness of about 120 nm.

For example, when thermal oxidation for 30 minutes using water vapor of 900° C. is performed to provide silicon oxide film 24 and silicon oxide film 24 on the region other than n++ region 9 is removed by a hydrofluoric acid treatment, silicon oxide film 24 on n++ region 9 can have a thickness of about 120 nm. Note that, as has been described above, when silicon oxide film 24 on n++ region 9 has a thickness of not less than 60 nm, silicon oxide film 24 can function suitably as a diffusion mask in providing p+ region 10.

Furthermore, a diffusion mask 25, such as silicon oxide film, is provided on the light-receiving surface of n type silicon substrate 4, and thereafter a solution having dissolved in an alcohol-based solvent a polymer having an organic macromolecule reacted with a boron compound is applied on the back surface of n type silicon substrate 4 and dried, and subsequently a heat treatment is performed to diffuse a p type impurity of boron in an exposed portion of the back surface of n type silicon substrate 4 to thus provide p+ region 10 and p+ region 71.

Then, as shown in FIG. 4(f), a first back surface passivation film 11 is provided on the back surface of n type silicon substrate 4. Herein, first back surface passivation film 11 can be provided for example as follows.

Initially, silicon oxide film 24, diffusion mask 25, and a glass layer provided by boron diffusion into silicon oxide film 24 and diffusion mask 25 on n type silicon substrate 4 are removed by a hydrofluoric acid treatment.

Then, first back surface passivation film 11, such as silicon oxide film, that also serves as a diffusion mask is provided on the back surface of n type silicon substrate 4 for example by a CVD method or applying and firing SOG (spin-on-glass) or the like.

Then, the light-receiving surface of n type silicon substrate 4 is spin-coated or the like with a liquid mixture 27 containing at least a phosphorus compound, titanium alkoxide, and alcohol and is then dried. Herein, liquid mixture 27 is applied in order to provide the light-receiving surface of n type silicon substrate 4 with an n++ region as light-receiving surface diffusion layer 6 and also provide titanium oxide film as anti-reflection film 12. Furthermore, the phosphorus compound of liquid mixture 27 can be phosphorus pentaoxide, the titanium alkoxide of liquid mixture 27 can be tetraisopropyl titanate, and the alcohol of liquid mixture 27 can be isopropyl alcohol, for example.

Then, as shown in FIG. 4(g) and FIG. 4(j), light-receiving surface diffusion layer 6 that is an n+ region and anti-reflection film 12 are provided on the light-receiving surface of n type silicon substrate 4. Herein, light-receiving surface diffusion layer 6 and anti-reflection film 12 can be provided by subjecting to a heat treatment the liquid mixture 27 that has been applied to the light-receiving surface of n type silicon substrate 4 and dried. This heat treatment causes n type impurity, or phosphorus, to diffuse in the light-receiving surface of n type silicon substrate 4 to provide light-receiving surface diffusion layer 6 throughout the light-receiving surface of n type silicon substrate 4 and also provide phosphorus containing titanium oxide film that serves as anti-reflection film 12. After the heat treatment, light-receiving surface diffusion layer 6 has a sheet resistance value for example of 30-150 w, desirably 80±20Ω/□

Then, as shown in FIG. 4(g) and FIG. 4(j), second back surface passivation film 8 is provided on the back surface of n type silicon substrate 4 and light-receiving surface passivation film 13 is also provided on light-receiving surface diffusion layer 6 of the light-receiving surface of n type silicon substrate 4. Herein, second back surface passivation film 8 and light-receiving surface passivation film 13 can be provided for example as follows.

N type silicon substrate 4 is thermally oxidized by oxygen or water vapor. This provides second back surface passivation film 8 formed of silicon oxide film between the back surface of n type silicon substrate 4 and first back surface passivation film 11, and light-receiving surface passivation film 13 formed of silicon oxide film between the light-receiving surface diffusion layer 6 and anti-reflection film 12 on the light-receiving surface of n type silicon substrate 4.

It is believed that light-receiving surface passivation film 13 is provided between light-receiving surface diffusion layer 6 and anti-reflection film 12 because anti-reflection film 12 in the concaves of concave-convex structure 5 of the light-receiving surface is increased in thickness and thus has a portion cracked, and this cracked portion allows oxygen or water vapor to enter therethrough and silicon oxide film, as light-receiving surface passivation film 13 to be grown. Furthermore, it is believed that anti-reflection film 12 in the convexes of concave-convex structure 5 of the light-receiving surface is reduced in thickness, and accordingly, oxygen or water vapor permeates and silicon oxide film as light-receiving surface passivation film 13 is grown.

Furthermore, it is believed that second back surface passivation film 8 is provided between the back surface of n type silicon substrate 4 and first back surface passivation film 11 because first back surface passivation film 11 at the back surface of n type silicon substrate 4 is a film provided by a CVD method or the like, and accordingly, oxygen or water vapor permeates into first back surface passivation film 11 and thereby silicon oxide film as second back surface passivation film 8 is grown.

Note that second back surface passivation film 8 and light-receiving surface passivation film 13 can also be provided by performing a heat treatment for providing light-receiving surface diffusion layer 6 and anti-reflection film 12, followed by switching a gas and performing thermal oxidation by oxygen or water vapor.

Then, as shown in FIG. 4(h), a portion of back surface passivation film 14 is removed to expose a portion of n++ region 9 and a portion of p+ region 10 from back surface passivation film 14. Herein, a portion of back surface passivation film 14 can be removed for example as follows. An etching paste is applied to a portion of back surface passivation film 14 by screen printing or the like, and the etching paste is then heated or the like. Thereafter the etching paste can be ultrasonically cleaned and then treated with acid and thus removed. The etching paste can for example be an etching paste containing: at least one selected from the group consisting of phosphoric acid, hydrogen fluoride, ammonium fluoride and ammonium hydrogen fluoride as an etching component; water; an organic solvent; and thickener.

Then, as shown in FIG. 4(i), electrode for n type 2 is provided on n++ region 9, and electrode for p type 3 is provided on p+ region 10. Herein, electrode for n type 2 and electrode for p type 3 can be provided for example as follows. Silver paste is applied to a predetermined location on back surface passivation film 14 by screen printing and the silver paste is then dried and thereafter fired. Back electrode type solar cell 1 of the first embodiment can thus be produced.

### Second Embodiment

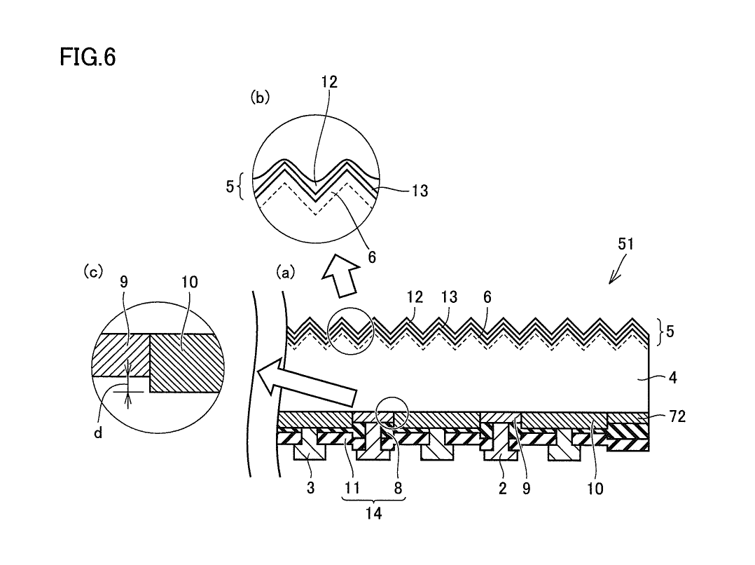

FIG. 5 shows a schematic plan view of a back surface of a back electrode type solar cell of a second embodiment. FIG. 6(a) shows a schematic cross sectional view along a line VI-VI of FIG. 5, and FIG. 6(b) shows a schematic enlarged cross sectional view of a portion of a light-receiving surface of n type silicon substrate 4 shown in FIG. 6(a), and FIG. 6(c) is a schematic enlarged cross sectional view for illustrating a difference in thickness between n++ region 9 and p+ region 10 shown in FIG. 6(a).

In a back electrode type solar cell 51 of the second embodiment, a peripheral edge semiconductor region of the back surface of n type silicon substrate 4 is an n++ region 72 as a semiconductor region of n type, and, of electrode for n type 2 and electrode for p type 3, outermost, opposite electrodes disposed on the back surface of n type silicon substrate 4 are electrodes for p type 3 having a conductivity type that is different from that of n type silicon substrate 4. In other words, also in back electrode type solar cell 51 of the second embodiment, on a peripheral edge of n type silicon substrate 4, no electrodes are provided, and n++ region 72 as a peripheral edge semiconductor region is out of contact with any electrodes.

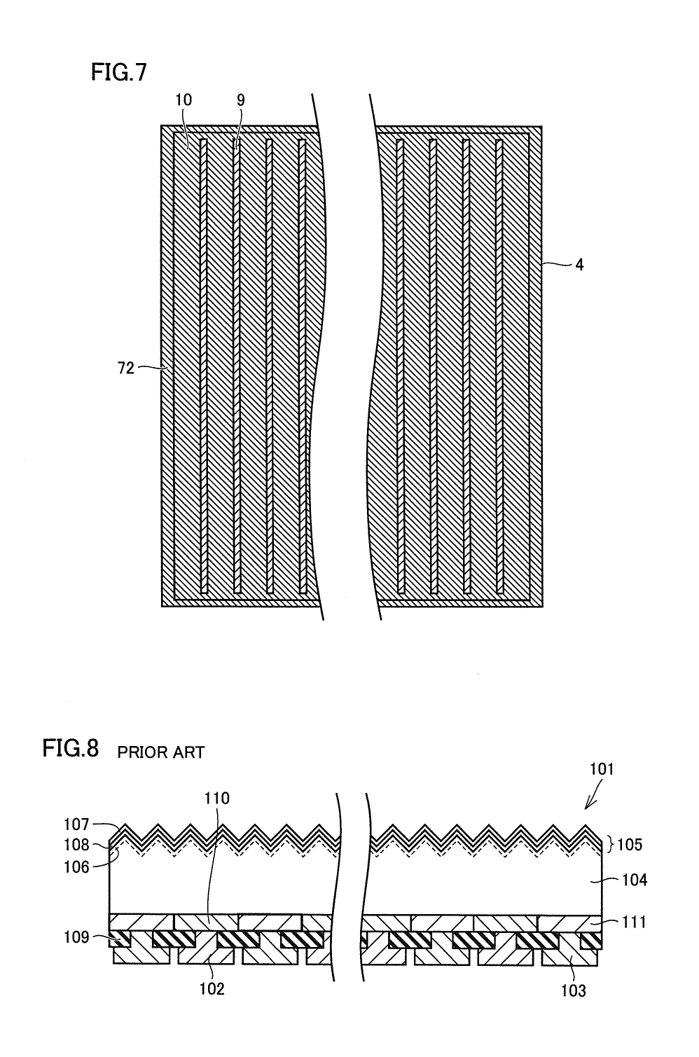

FIG. 7 shows a schematic plan view of the back surface of n type silicon substrate 4 when electrode for n type 2, electrode for p type 3, and back surface passivation film 14 are removed from back electrode type solar cell 51 of the second embodiment.

Note that in back electrode type solar cell 51 of the second embodiment n++ region 72 is provided at a surrounding of a forming region of n++ region 9 and p+ region 10 in the back surface of n type silicon substrate 4, as a peripheral edge semiconductor region that is a semiconductor region out of contact with any electrodes. Furthermore, p+ region 10 is provided to surround strip-shaped n++ region 9, and n++ region 9 and n++ region 72 have the same, p type conductivity type.

As shown in FIG. 7, by providing n++ region 72 as a peripheral edge semiconductor region of a conductivity type that is different from that of p+ region 10, even if n++ region 72 is provided at the outside of the forming region of n++ region 9 and p+ region 10, n++ region 9 and p+ region 10 can be electrically separated.

Even if back electrode type solar cell 51 is biased in a reverse direction (or a reverse bias voltage is applied thereto), it can reduce an occurrence of a leakage current passing through the peripheral edge of the back surface of back electrode type solar cell 51 into an electrode, since n++ region 72 as a peripheral edge semiconductor region is out of contact with any electrodes.

Furthermore, also in the back surface of electrode type solar cell 51, of n++ region 9 and p+ region 10, p+ region 10 as a semiconductor region of a conductivity type that is different from that of n type silicon substrate 4, preferably has a larger total area. In that case, there is a tendency that back electrode type solar cell 51 provides a short-circuit current in an increased amount.

Note that while in the example shown in FIG. 7 p+ regions 10 are all connected to form a single semiconductor region, it is not a requirement to connect p+ region 10 altogether. Furthermore, while in the example shown in FIG. 7 n++ region 9 is divided into a plurality thereof, n++ region 9 may have a portion connected to another portion thereof.

Furthermore, in back electrode type solar cell 51 of the second embodiment, outermost, opposite electrodes disposed on the back surface of n type silicon substrate 4 are electrodes for p type 3, respectively, which allows the back surface of back electrode type solar cell 51 to be a rotationally symmetrical structure. Accordingly, when a plurality of back electrode type solar cells 51 are aligned to produce a solar cell module, back electrode type solar cell 51 shown in FIG. 5 may be placed with its back surface upside down.

Furthermore, in back electrode type solar cell 51 of the second embodiment, of electrode for n type 2 and electrode for p type 3, outermost, opposite electrodes for p type 3 disposed on the back surface of n type silicon substrate 4, are electrodes for a conductivity type that is different from that of n++ region 72 as a peripheral edge semiconductor region.

The remainder of the present embodiment is similar to that of the first embodiment, and accordingly, will not be described repeatedly.

<Others>

In back electrode type solar cell 1 of the first embodiment and back electrode type solar cell 51 of the second embodiment, in operation, n++ region 9 provided with electrode for n type 2 and light-receiving surface diffusion layer 6 that is an n+ region are separated only with a bulk of n type silicon substrate 4 posed therebetween and are thus not affected by each other's potential.

Furthermore, while the above is described for a case using n type silicon substrate 4, a p type silicon substrate can alternatively be used. In that case, if light-receiving surface diffusion layer 6 exists, light-receiving surface diffusion layer 6 will be a p+ region formed by diffusing a p type impurity and anti-reflection film 12 will be a film containing a p type impurity, and the remainder in structure can be similar to the above described structure using n type silicon substrate 4.

Furthermore, if a p type silicon substrate is used, then, in order to obtain a short-circuit current in a larger amount, it is preferable that in the back surface of the back electrode type solar cell, of n++ region 9 on which electrode for n type 2 is provided and p+ region 10 on which electrode for p type 3 is provided, n++ region 9 of a conductivity type different from that of the p type silicon substrate preferably has a total area larger than that of p+ region 10. Furthermore, in that case, p+ region 10 may be divided in a direction perpendicular to its lengthwise direction, and n++ region 9 can be provided between the divisions of p+ region 10. Furthermore, in that case, n++ region 9 may be divided in a direction perpendicular to its lengthwise direction, and p+ region 10 can be provided between the divisions of n++ region 9.

Furthermore, the concept of the back electrode type solar cell of the present invention includes not only a back electrode type solar cell of a configuration in which both an electrode for p type and an electrode for n type are formed only on a surface as a back surface of a semiconductor substrate but also a solar cell of a configuration of the MWT (Metal Wrap Through) type (a solar cell configured such that a part of an electrode is arranged in a through hole provided on a semiconductor substrate).

### INDUSTRIAL APPLICABILITY

A back electrode type solar cell in accordance with the present invention is widely applicable to back electrode type solar cells in general.

### REFERENCE SIGNS LIST

1: back electrode type solar cell, 2: electrode for n type, 3: electrode for p type, 4: n type silicon substrate, 5, 105: concave-convex structure, 6: light-receiving surface diffusion layer, 8: second back surface passivation film, 9: n++ region, 10: p+ region, 11: first back surface passivation film, 12: anti-reflection film, 13: light-receiving surface passivation film, 14: back surface passivation film, 21: texture mask, 22, 23: diffusion mask, 24: silicon oxide film, 25: diffusion mask, 27: liquid mixture, 71: p+ region, 72: n++ region, 101: back electrode type solar cell, 102: metal contact for n type, 103: metal contact for p type, 104: n type silicon wafer, 105: concave-convex structure, 106: n type front surface diffusion region, 107: antireflection coating, 108: dielectric passivation layer, 109: oxide layer, 110: n+ region, 111: texture mask.

1. A back electrode type solar cell comprising:
a silicon substrate of a first conductivity type or a second conductivity type;
a first conductivity type semiconductor region and a second conductivity type semiconductor region provided at a back surface of said silicon substrate opposite to a light-receiving surface of said silicon substrate;
an electrode for said first conductivity type provided in said first conductivity type semiconductor region;
an electrode for said second conductivity type provided in said second conductivity type semiconductor region; and
a peripheral edge semiconductor region provided at a surrounding of a forming region of said first conductivity type semiconductor region and said second conductivity type semiconductor region in said back surface of said silicon substrate,
said peripheral edge semiconductor region being out of contact with said electrode for said first conductivity type and said electrode for said second conductivity type.

2. The back electrode type solar cell according to claim 1, wherein:
said second conductivity type semiconductor region is provided at a surrounding of said first conductivity type semiconductor region; and
said peripheral edge semiconductor region has a conductivity type identical to that of said first conductivity type semiconductor region.

3. The back electrode type solar cell according to claim 1, wherein, of said first conductivity type semiconductor region and said second conductivity type semiconductor region, a semiconductor region of a conductivity type different from that of said silicon substrate has a larger total area.

4. The back electrode type solar cell according to claim 1, wherein, of said electrode for said first conductivity type and said electrode for said second conductivity type, outermost electrodes disposed on said back surface of said silicon substrate are electrodes for a single conductivity type.

5. The back electrode type solar cell according to claim 1, wherein, of said electrode for said first conductivity type and said electrode for said second conductivity type, outermost electrodes disposed on said back surface of said silicon substrate are electrodes for a conductivity type different from that of said peripheral edge semiconductor region.

6. The back electrode type solar cell according to claim 1, wherein a light-receiving surface diffusion layer of a conductivity type identical to that of said silicon substrate is provided on a light-receiving surface side of said silicon substrate.

7. The back electrode type solar cell according to claim 6, further comprising:
a light-receiving surface passivation film provided on said light-receiving surface diffusion layer; and
an anti-reflection film provided on said light-receiving surface passivation film, wherein said anti-reflection film is titanium oxide film containing an impurity of a conductivity type identical to that of said silicon substrate.
